(19) United States
(12) Patent Application Publication
(10) Pub. No.: US 2022/0246828 A1
(43) Pub. Date: Aug. 4, 2022

(54) SENSOR DEVICE

(71) Applicant: TAIYO YUDEN CO., LTD., Tokyo (JP)

(72) Inventor: Yosuke ONDA, Tokyo (JP)

(73) Assignee: TAIYO YUDEN CO., LTD., Tokyo (JP)

(21) Appl. No.: 17/723,809

(22) Filed: Apr. 19, 2022

Related U.S. Application Data
(63) Continuation of application No. PCT/JP2020/037456, filed on Oct. 1, 2020.

(30) Foreign Application Priority Data
Oct. 21, 2019 (JP) 2019-192305

(51) Int. Cl. H01L 41/08; H01L 41/083; H01L 41/047; H01L 41/113; H01L 41/18

(52) U.S. Cl. CPC H01L 41/0825; H01L 41/083; H01L 41/18; H01L 41/081; H01L 41/1132; H01L 41/0471

(57) ABSTRACT

A sensor device includes a substrate; a piezoelectric film on the substrate; a lower electrode and an upper electrode that face each other with at least part of the piezoelectric film sandwiched therebetween; and a sensitive film in a region on the upper electrode that approximately corresponds to a resonance region, the resonance region being defined as a region in a plan view in which the lower electrode and the upper electrode face each other with the piezoelectric film sandwiched therebetween and in which a resonance in a thickness longitudinal vibration mode occurs, the sensitive film being absent in regions on the upper electrode and on the lower electrode that are outside of the resonance region in the plan view.

### TECHNICAL FIELD

The present invention relates to a sensor device using a piezoelectric thin film resonator such as an FBAR (Film Bulk Acoustic Resonator).

### BACKGROUND ART

The FBAR is a resonator in the GHz band used in filters, duplexers, and the like of mobile communication devices. Development of odor sensors in which a sensitive film on which a specific gas is adsorbed is applied to a piezoelectric resonator such as QCM (Quartz Crystal Microbalance) and SAW (Surface Acoustic Wave) and a frequency change corresponding to the mass change is detected is underway (see Non-Patent Literatures 1 and 2).

### CITATION LIST

### Non-Patent Literature

Non-Patent Literature 1: Matthew L. Johnston, Columbia University, New York, N.Y., USA MEMS 2012, Paris, FRANCE, 29 Jan.-2 Feb. 2012 846-849

Non-Patent Literature 2: Mono Onoe, Hiromichi Jumonji, “Analysis of Piezoelectric Resonators Vibrating in Trapped Energy Modes”, Journal of the Institute of Electronics, Information and Communication Engineers, Vol. 48, 1965

### SUMMARY OF THE INVENTION

When a sensitive film is applied onto a piezoelectric resonator, the resonance properties change. Normally, a shift of the resonant frequency to the lower frequency side is observed, but a significant decrease in the Q-value or spurious occurs depending on the condition of application of the sensitive film. The decrease in the Q-value or the occurrence of spurious causes oscillation failure and destabilization of the oscillation frequency, and deteriorates the detection property of a gas or odor. As compared with QCM that resonates in the MHz band, the FBAR that resonates in the GHz band is more sensitive to the influence of the sensitive film on the resonance properties, and it is necessary to carefully manage the formation conditions of the sensitive film.

In view of the circumstances as described above, it is an object of the present invention to provide a sensor device capable of suppressing deterioration of resonance properties due to a sensitive film.

In order to achieve the above-mentioned object, a sensor device according to an embodiment of the present invention includes: a substrate; a piezoelectric film; a lower electrode and an upper electrode; and a sensitive film.

The piezoelectric film is provided on the substrate.

The lower electrode and the upper electrode face each other with at least part of the piezoelectric film sandwiched therebetween.

The sensitive film is provided to a resonance region of the upper electrode in which the lower electrode and the upper electrode face each other with the piezoelectric film sandwiched therebetween.

In the sensor device, by providing the sensitive film to a resonance region, a significant decrease in the Q-value and occurrence of spurious are prevented. As a result, it is possible to suppress deterioration of resonance properties and improve the detection property of a gas.

The sensitive film may be provided in the resonance region on the upper electrode.

The sensitive film may be provided at a portion of the upper electrode corresponding to the resonance region.

The resonance region may have an elliptical shape.

The resonance region may have a first major axis and a first minor axis, and the sensitive film may have a second major axis and a second minor axis when viewed in a plan view from a lamination direction of the sensor device. In this case, a difference between the first major axis and the second major axis is smaller than 20 μm and a difference between the first minor axis and the second minor axis is smaller than 20 μm.

In the resonance region, a gap may be provided between the substrate and the lower electrode.

The substrate may include a hole that is connected to the gap. In this case, the sensor device further includes a member that closes the hole.

In the resonance region, the piezoelectric film, the upper electrode, and the lower electrode may each include a projecting curved surface portion that forms a gap between the substrate and the lower electrode. The sensitive film is provided to the projecting curved surface portion of the upper electrode.

The sensitive film may be an inorganic film, an organic polymer film, or an organic dye film.

The sensitive film may be formed of a cellulose resin, a fluorine resin, an acrylic resin, or a conductive polymer.

### ADVANTAGEOUS EFFECTS OF INVENTION

In accordance with the present invention, it is possible to suppress deterioration of resonance properties due to a sensitive film.

### BRIEF DESCRIPTION OF DRAWINGS

FIG. 1 is a diagram showing a configuration of a sensor device according to an embodiment of the present invention, Part (a) being a plan view, Part (b) being a cross-sectional view taken along the line A-A in Part (a).

FIG. 2 is a plan view showing configurations of sensor devices according to Comparative Examples 1 and 2.

FIG. 3 shows experimental results showing the resonance properties of the sensor devices shown in FIG. 1 and FIG. 2.

FIG. 4 is an equivalent circuit diagram of a piezoelectric resonator.

FIG. 5 is a cross-sectional view of each step describing a method of producing the sensor device in FIG. 1.

FIG. 6 is a plan view showing a modified example of the configuration of the sensor device in FIG. 1.

### EMBODIMENTS FOR CARRYING OUT THE INVENTION

Hereinafter, embodiments of the present invention will be described with reference to the drawings.

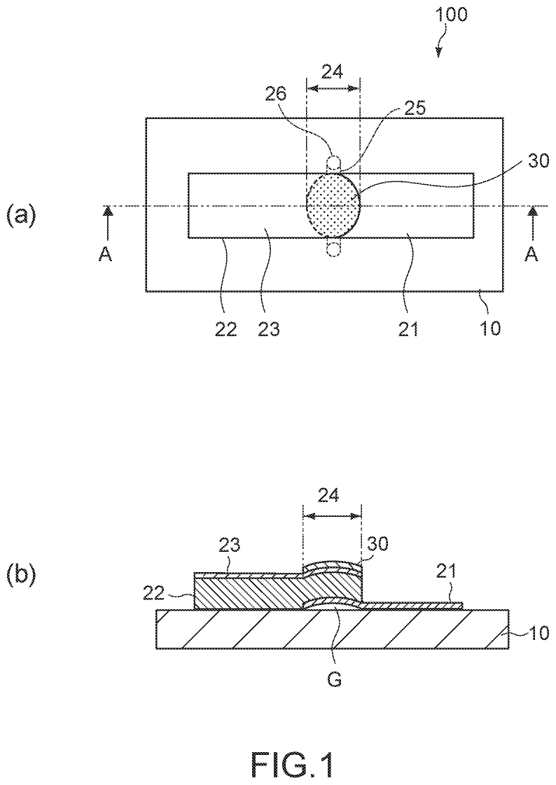

FIG. 1 is a diagram showing a configuration of a sensor device according to an embodiment of the present invention, Part (a) being a plan view, Part (b) being a cross-sectional view taken along the line A-A in Part (a).

### Sensor Device

A sensor device 100 according to this embodiment includes an FBAR type piezoelectric resonator including a substrate 10, a piezoelectric film 22, a lower electrode 21 and an upper electrode 23 that face each other with at least part of the piezoelectric film 22 sandwiched therebetween, and a sensitive film 30.

As the substrate 10, for example, a ceramic substrate such as a quartz substrate, a glass substrate, and an alumina substrate can be used in addition to a semiconductor substrate such as a silicon (Si) substrate and a gallium arsenide (GaAs) substrate.

The lower electrode 21 is formed on the substrate 10 in a predetermined shape. The thickness of the lower electrode 21 is, for example, 240 nm. The lower electrode 21 includes a metal single-layer film of aluminum (Al), copper (Cu), chromium (Cr), molybdenum (Mo), tungsten (W), tantalum (Ta), platinum (Pt), ruthenium (Ru), rhodium (Rh), or iridium (Ir) or a lamination film thereof.

The piezoelectric film 22 is formed on the substrate 10 in a predetermined shape so as to cover part of the lower electrode 21. The thickness of the piezoelectric film 22 is, for example, 500 nm. The piezoelectric film 22 includes, for example, a piezoelectric material containing, as a main component, aluminum nitride (AlN) having the main axis of the (002) direction. As the piezoelectric film 22, for example, a ZnO film can be used in place of the AlN film.

The upper electrode 23 is formed above the substrate 10 in a predetermined shape so as to cover at least part of the piezoelectric film 22. The thickness of the upper electrode 23 is, for example, 240 nm. The upper electrode 23 includes a single-layer film of the metal material listed in the lower electrode 21 or a lamination film thereof.

The sensor device 100 has a resonance region 24. The resonance region 24 is a region in which the lower electrode 21 and the upper electrode 23 face each other with the piezoelectric film 22 sandwiched therebetween. In the resonance region 24, a gap G is provided between the substrate 10 and the lower electrode 21. In this embodiment, in the resonance region 24, the piezoelectric film 22, the lower electrode 21, the upper electrode 23 each include a projecting curved surface portion that forms the gap G between the substrate 10 and the lower electrode 21. The planar shape of the projecting curved surface of the upper electrode 23 is, for example, an elliptical shape having a major axis of 270 μm and a minor axis of 180 μm. The resonance region 24 is a region that resonates in a thickness longitudinal vibration mode when a voltage signal having a predetermined frequency is applied between the lower electrode 21 and the upper electrode 23. The resonant frequency of the resonance region 24 is not particularly limited, and is typically a frequency in the GHz band.

Note that the planar shape of the resonance region 24 may be another shape such as a circular shape and a polygonal shape. In particular, by making the planar shape of the resonance region 24 an ellipse or a polygonal shape, the generation of a vibration mode propagating in the lateral direction can be suppressed as compared with the case where the planar shape of the resonance region 24 is a quadrangle (square or rectangle), and therefore, deterioration of resonance properties can be prevented.

In the resonance region 24, the gap G is a dome-shaped space formed between the flat upper surface of the substrate 10 and the lower electrode 21. The dome-shaped space is, for example, a space having a shape in which the height of the gap G is low at the periphery of the gap G and the height of the gap G increases toward the center of the gap G. An introduction path 25 formed by introducing an etchant when forming the gap G is provided below the lower electrode 21. The vicinity of the tip of the introduction path 25 is not covered with the piezoelectric film 22 or the like, and the tip of the introduction path 25 is a hole 26. The hole 26 is an introduction port for introducing an etchant when forming the gap G.

The formation position of the hole 26 is not particularly limited, but is favorably provided in the vicinity of the resonance region 24. The hole 26 is closed using an appropriate material after forming the gap G. As a result, since the communication of the gap G with the outside air can be cut off, deterioration of resonance properties due to an invading gas into the gap G can be prevented. The material for closing the hole 26 is not particularly limited, and the hole 26 may be closed by part of the sensitive film 30.

The sensitive film 30 is formed of a material capable adsorbing a gas to be detected. The material forming the sensitive film can be appropriately selected in accordance with the type of the gas to be detected. For example, an organic polymer film (a high-molecular-weight film, an organic low-molecular-weight film), an organic dye film, an inorganic film, or the like can be used. More specifically, examples of the sensitive film 30 include, but not limited to, a cellulose resin, a fluorine resin, an acrylic resin, and a conductive polymer. As the method of forming the sensitive film 30, a vapor deposition method, a sputtering method, or a CVD (Chemical Vapor Deposition) method can be used in addition to a method of dissolving a material of a sensitive film in a solvent and applying it.

As the organic polymer material, for example, a homopolymer having a single structure such as polystyrene, polymethylmethacrylate, 6-nylon, cellulose acetate, poly-9,9-dioctylfluorene, polyvinylalcohol, polyvinylcarbazole, polyethyleneoxide, polyvinyl chloride, poly-p-phenylene ether sulfone, poly-1-butene, polybutadiene, polyphenylmethylsilane, polycaprolactone, polybisphenoxyphosphazene, and polypropylene, a copolymer that is a copolymer of two or more homopolymers, or a blended polymer in which these are mixed can be used.

For example, as the organic low-molecular-weight material, tris(8-hydroxyquinolinato)aluminum (Alq3), naphthyldiamine (α-NPD), BCP (2,9-dimethyl-4,7-diphenyl-1,10-phenanthroline), CBP (4,4′-N,N′-dicarbazole-biphenyl), copper phthalocyanine, fullerene, pentacene, anthracene, thiophene, Ir(ppy(2-phenylpyridinato))₃, a triazinethiol derivative, a dioctylfluorene derivative, tetracontane, or parylene can be used.

For example, as the inorganic material, alumina, titania, vanadium(V) pentoxide, tungsten oxide, lithium fluoride, magnesium fluoride, aluminum, gold, silver, tin, indium⋅tin⋅oxide (ITO), carbon nanotube, sodium chloride, or magnesium chloride can be used.

The sensitive film 30 is provided in the resonance region 24. In this embodiment, the sensitive film 30 is provided only in the resonance region 24 on the upper electrode 23, and is provided to a portion approximately corresponding to the resonance region 24 on the upper electrode 23. In this embodiment, the portion corresponding to the resonance region 24 is the surface of the elliptical dome portion of the upper electrode 23, and the sensitive film 30 is provided to a projecting curved surface portion of the upper electrode 23. The resonance region 24 is formed in an elliptical shape having the same major axis and minor axis as those of the dome portion. The thickness of the sensitive film 30 is not particularly limited, and is, for example, 250 nm.

The sensitive film 30 includes a coating film that contains the above-mentioned polymer material and is selectively applied to the resonance region 24 using a mask material (not shown) and dried. The sensitive film 30 may be formed in a region wider or narrower than the resonance region 24 or may be provided at a position offset from the resonance region in accordance with the aperture accuracy or position accuracy of the mask described above.

Here, when a sensitive film is applied onto a piezoelectric resonator, the vibration mode is affected and resonance properties change. Normally, a shift of the resonant frequency to the lower frequency side is observed, but a significant decrease in the Q-value or spurious occurs depending on the condition of application of the sensitive film. The decrease in the Q-value or the occurrence of spurious causes oscillation failure and destabilization of the oscillation frequency, and deteriorates the detection property of a gas or odor. As compared with QCM that resonates in the MHz band, the FBAR that resonates in the GHz band is more sensitive to the influence of the sensitive film on the resonance properties, and it is necessary to carefully manage the formation conditions of the sensitive film.

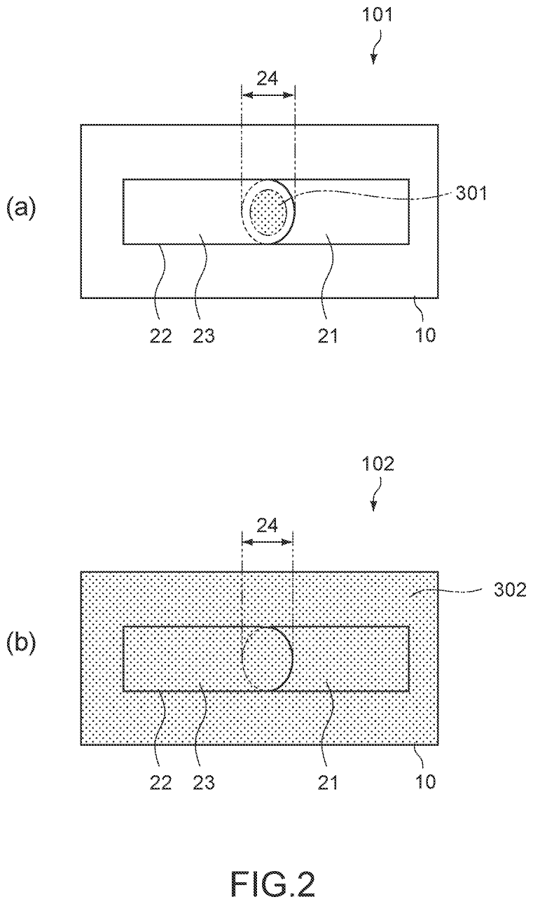

The present inventors prepared a sensor device 101 according to a Comparative Example 1 schematically shown in Part (a) of FIG. 2 and a sensor device 102 according to a Comparative Example 2 shown in Part (b) of FIG. 2 in addition to the sensor device 100 according to this embodiment shown in FIG. 1, and measured frequency properties thereof. The sensor structures in the Comparative Examples 1 and 2 are the same as that of the sensor device 100 according to this embodiment, and only the application form of the sensitive film 30 differs. In the Comparative Example 1, a sensitive film 301 is formed in a region narrower than the resonance region 24, which has an elliptical shape having a major axis and a manor axis 20 μm smaller than those of the resonance region 24. Meanwhile, in the Comparative Example 2, a sensitive film 302 is formed on the entire surface of the substrate 10.

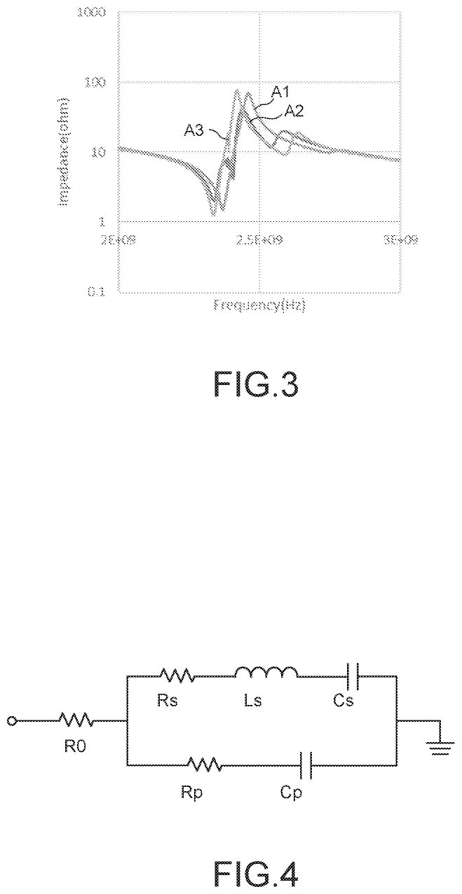

The resonance properties of the sensor devices 100, 101, and 102 are shown in FIG. 3 in comparison with each other. In the figure, the vertical axis and the horizontal axis respectively represent a frequency and an impedance, and a waveform A1, a waveform A2, and a waveform A3 respectively represent the resonance properties of the sensor device 100 in FIG. 1, the resonance properties of the sensor device 101 in Part (a) of FIG. 2, and the resonance properties of the sensor device 102 in Part (b) of FIG. 2. Further, FIG. 4 shows an equivalent circuit of a sensor unit (no sensitive film) of each of the sensor devices 100, 101, and 102. Here, a resistance R0, a resistance Rs, a resistance Rp a capacitor Cs, a capacitor Cp, and an inductor Ls are respectively set to 0.568Ω, 0.185Ω, 0.141Ω, 161.386 fF, 3.913 pF, and 27.684 nH, and the resonant frequency of a resonance unit 100a (resonance region 24) with no sensitive film is set to 2.4 GHz.

As shown in FIG. 3, in the sensor device 100 (the waveform A1) according to this embodiment, stable oscillation properties can be achieved with a single resonance property without spurious.

Meanwhile, in the sensor device 101 (waveform A2) according to the Comparative Example 1 and the sensor device 102 (waveform A3) according to the Comparative Example 2, spurious resonance is recognized in addition to the main resonance and also the Q-value decreases. That is, as compared with the waveform A1, deterioration of resonance properties affects the oscillation properties. Normally, in a piezoelectric resonator, elastic waves are confined inside the resonator due to energy confinement and a single resonance property can be achieved. In the case of the Comparative Examples 1 and 2, it is clear that the formation of the sensitive films 301 and 302 deviates from the conditions of energy confinement.

As described above, in accordance with this embodiment, by providing the sensitive film 30 to a portion corresponding to the resonance region 24 on the upper electrode 23, it is possible to maintain stable resonance properties in the resonance region 24. As a result, it is possible to improve the detection property of a gas or odor to be detected.

Further, from the results of the Comparative Example 1, the differences between the main axis and minor axis of the sensitive film having an elliptical shape in a plan view and the major axis and minor axis of the resonance region 24 having an elliptical shape similarly are favorably less than 20 μm.

### Method of Producing Sensor Device

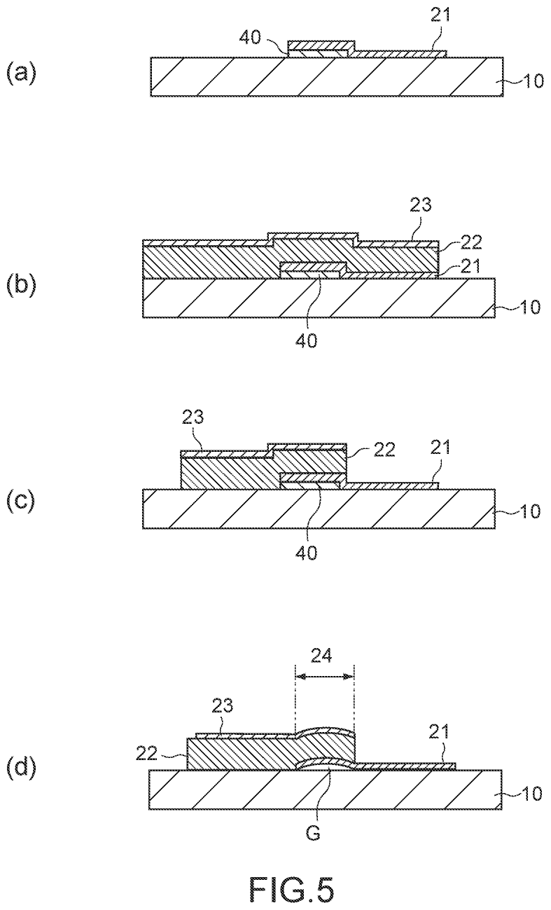

Next, a method of producing the sensor device 100 according to this embodiment will be described. Parts (a) to (d) of FIG. 5 are each a cross-sectional view showing a method of producing the sensor device 100.

As shown in Part (a) of FIG. 5, a sacrificial layer 40 is formed on the substrate 10 using, for example, a sputtering method, a vapor deposition method, or a chemical vapor deposition method (CVD method). For example, a magnesium oxide (MgO) film can be used as the sacrificial layer 40, and the sacrificial layer 40 is provided in a region that includes a region that will form the gap G. The film thickness of the sacrificial layer 40 is, for example, approximately 20 nm.

Subsequently, for example, sputtering is performed under an argon (Ar) gas atmosphere to deposit a metal film on the substrate 10 and the sacrificial layer 40. The deposition of the metal film may be performed using a vapor deposition method or a CVD method. The metal film is selected from at least one of the materials (Al, Cu, Cr, Mo, W, Ta, Pt, Ru, Rh, or Ir) listed for the lower electrode 21. After that, for example, photolithography and etching are performed to make the metal film in a desired shape, thereby forming the lower electrode 21. At this time, part of the lower electrode 21 is caused to cover the sacrificial layer 40. Note that the lower electrode 21 may be formed by a lift-off method.

Subsequently, as shown in Part (b) of FIG. 5, the piezoelectric film 22 including an AlN film is deposited on the substrate 10 and the lower electrode 21. The deposition of the piezoelectric film 22 can be performed by a one-dimensional sputtering method using an aluminum metal target under a nitrogen-containing atmosphere (e.g., under a mixed gas atmosphere of nitrogen and a rare gas (such as Ar)).

Subsequently, for example, sputtering is performed under an Ar gas atmosphere to deposit a metal film on the piezoelectric film 22. The deposition of the metal film may be performed using a vapor deposition method or a CVD method. Similarly to the above, also this metal film is selected from at least one of Al, Cu, Cr, Mo, W, Ta, Pt, Ru, Rh, or Ir.

After that, as shown in Part (c) of FIG. 5, photolithography and etching are performed to make the metal film in a desired shape, thereby forming the upper electrode 23. The upper electrode 23 may be formed by a lift-off method. Subsequently, for example, photolithography method and etching are performed to make the piezoelectric film 22 in a desired shape. Further, the lower electrode 21 and the sacrificial layer 40 are selectively etched to form a hole 26 (see Part (a) of FIG. 1).

Subsequently, as shown in Part (d) of FIG. 5, an etchant is introduced from the hole 26 to etch the sacrificial layer 40. Here, the stress of the lamination film of the lower electrode 21, the piezoelectric film 22, and the upper electrode 23 is set to be the compressive stress in advance. As a result, the lamination film swells up when the etching of the sacrificial layer 40 is completed, and the resonance region 24 having the gap G having a dome shaped is formed between the substrate 10 and the lower electrode 21. Further, also the introduction path 25 that connects the gap G and the hole 26 to each other is formed. After that, by providing the sensitive film 30 to a portion corresponding to the resonance region 24 on the upper electrode 23, the sensor device 100 shown in FIG. 1 is prepared.

As a method of forming the sensitive film 30, for example, a cellulose resin, a fluorine resin, an acrylic resin, or a conductive polymer is dissolved in a solvent such as acetone, methanol, ethanol, toluene, THF, MEK, NMP, heptane, and water. Another solvent may be used in addition to the above. However, the solvent described above has relatively high volatility (relatively low boiling point), and thus is suitable in that the sensitive film 30 is easy to dry and a uniform film can be deposited.

Subsequently, a sensitive film is selectively applied onto the resonance region 24 by a printing method using a metal mask, a cast dispense method, or the like.

While an embodiment of the present invention has been described above, it is needless to say that the present invention is not limited to the above-mentioned embodiment only, and various modifications can be made.

For example, although a sensor device having an air gap structure in which the resonance region 24 has been formed by forming the gap G between the substrate 10 and the lower electrode 21 has been described as an example in the embodiment described above, a sensor device having a cavity structure in which a cavity is provided in the top surface of the substrate 10, and a lamination region of a lower electrode, a piezoelectric film, and an upper electrode formed on the cavity is used as a resonance region may be provided. Alternatively, a sensor device having an acoustic reflective film structure may be adopted.

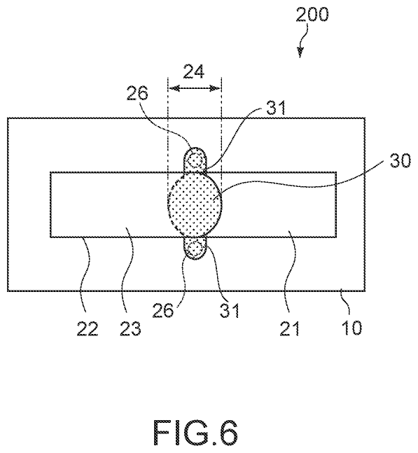

Further, as in a sensor device 200 shown in FIG. 6, a member 31 that closes the hole 26 of the substrate 10 may be further provided. The member 31 may be connected to the sensitive film 30 or does not necessarily need to be connected to the sensitive film 30. The member 31 closes the hole 26 connected to the gap G. The constituent material of the member 31 is not particularly limited, and the member 31 may be formed of the same material as that of the sensitive film 30. As a result, since the hole 26 of the substrate 10 can be closed by the member 31, it is possible to simultaneously perform the step of forming the sensitive film 30 and the step of forming the member 31.

What is claimed is:

1. A sensor device, comprising:
a substrate;
a piezoelectric film on the substrate;
a lower electrode and an upper electrode that face each other with at least part of the piezoelectric film sandwiched therebetween; and
a sensitive film in a region on the upper electrode that approximately corresponds to a resonance region, the resonance region being defined as a region in a plan view in which the lower electrode and the upper electrode face each other with the piezoelectric film sandwiched therebetween and in which a resonance in a thickness longitudinal vibration mode occurs, the sensitive film being absent in regions on the upper electrode and on the lower electrode that are outside of the resonance region in the plan view.

2. The sensor device according to claim 1, wherein the region on the upper electrode in which the sensitive film is provided is inside the resonance region in the plan view.

3. The sensor device according to claim 1, wherein the region in which the sensitive film is provided corresponds to an entirety of the resonance region in the plan view.

4. The sensor device according to claim 1, wherein the resonance region has an elliptical shape.

5. The sensor device according to claim 4, wherein the sensitive film also has an elliptical shape that has a shape and orientation similar to the elliptical shape of the resonance region such that differences in dimensions along a major axis and a minor axis of the elliptical shape are both within 20 μm from each other.

6. The sensor device according to claim 1, wherein in the resonance region, a gap is provided between the substrate and the lower electrode.

7. The sensor device according to claim 6,
wherein the substrate includes a hole that is connected to the gap, and
wherein the sensor device further includes a member that closes the hole.

8. The sensor device according to claim 6,
wherein in the resonance region, the piezoelectric film, the upper electrode, and the lower electrode each include a projecting curved surface portion that forms a gap between the substrate and the lower electrode, and
wherein the sensitive film is provided to the projecting curved surface portion of the upper electrode.

9. The sensor device according to claim 1, wherein the sensitive film is an inorganic film, an organic polymer film, or an organic dye film.

10. The sensor device according to claim 9, wherein the sensitive film is formed of a cellulose resin, a fluorine resin, an acrylic resin, or a conductive polymer.
